(19) United States
(12) Patent Application Publication
(10) Pub. No.: US 2026/0276717 A1
(43) Pub. Date: Sep. 17, 2026

(54) APPARATUS FOR SENSING INPUT VOLTAGE OF INVERTER

(71) Applicants: Hyundai Motor Company, Seoul (KR); Kia Corporation, Seoul (KR)

(72) Inventors: Seung Bae JEONG, Hwaseong-si (KR); Byung Kwon Han, Hwaseong-si (KR); Tae Hoon Bae, Hwaseong-si (KR)

(73) Assignees: Hyundai Motor Company, Seoul (KR); Kia Corporation, Seoul (KR)

(21) Appl. No.: 19/362,086

(22) Filed: Oct. 17, 2025

(30) Foreign Application Priority Data
Mar. 11, 2025 (KR) 10-2025-0031493

(51) Int. Cl. G01R 31/3835; G01R 31/36

(52) U.S. Cl. CPC G01R 31/3835; G01R 31/3644

(57) ABSTRACT

An apparatus for sensing an input voltage of an inverter includes a busbar assembly including a first terminal portion electrically connected to a battery and a second terminal portion branched from the first terminal portion, and a substrate including a contactor configured to allow the second terminal portion to be inserted into the contactor, and a voltage sensor configured to detect a voltage from the battery by receiving the voltage from the busbar assembly through the contactor.

### CROSS-REFERENCE TO THE RELATED APPLICATION

The present application claims priority from Korean Patent Application No. 10-2025-0031493 filed on Mar. 11, 2025, in the Korean Intellectual Property Office, the disclosure of which is incorporated herein by reference in its entirety.

### BACKGROUND OF THE PRESENT DISCLOSURE

### Field of the Present Disclosure

The present disclosure relates to an inverter input voltage sensing apparatus for sensing a voltage input to an inverter.

### Description of Related Art

A power conversion device has a function of converting alternating current (AC) power into direct current (DC) power and vice versa and is widely used in various electronic devices and industrial equipment. In particular, an inverter is a device configured to convert DC power into AC power and is used in solar power generation systems, electric vehicles, household appliances, industrial motor control systems, etc.

One important factor in operation of such an inverter is voltage sensing technology. The voltage sensing technology may be used to control the inverter by measuring an input voltage or an output voltage of the inverter and transmitting the resultant information to a control system.

Accurate voltage sensing may enhance the efficiency of power conversion, may prevent damage caused by overvoltage or undervoltage, and may ensure stable power supply.

For voltage sensing in the inverter, as mentioned above, a connection structure between an input terminal of the inverter and a voltage sensor is necessary.

The above matters disclosed in this section are merely for enhancement of understanding of the general background of the present disclosure and should not be taken as an acknowledgement or any form of suggestion that the matters form the related art already known to a person skilled in the art.

### BRIEF SUMMARY

Therefore, the present disclosure has been made in view of the above problems, and it is an aspect of the present disclosure to provide an inverter input voltage sensing apparatus including a structure configured to directly connect a busbar, to which an input voltage of an inverter is applied, to a substrate disposed with a voltage sensor, being configured for enhancing cost, space, and manufacturing process efficiencies.

Aspects of the present disclosure are not limited to the above-described aspect, and other aspects of the present disclosure not yet described will be more clearly understood by those skilled in the art from the following detailed description.

In accordance with an aspect of the present disclosure, the above and other aspects may be accomplished by the provision of an apparatus for sensing an input voltage of an inverter, including a busbar assembly including a first terminal portion electrically connected to a battery, and a second terminal portion branched from the first terminal portion, and a substrate including a contactor configured to allow the second terminal portion to be inserted into the contactor, and a voltage sensor configured to detect a voltage from the battery by receiving the voltage from the busbar assembly through the contactor.

In accordance with various aspects of the present disclosure, it may be possible to interconnect a busbar and the voltage sensor through simple components and a connection structure while omitting auxiliary portions such as fastening bolts, wires, connectors, etc.

As the input voltage sensing structure is simplified, it may be possible to reduce manufacturing costs and to reduce the space required for voltage sensing within the inverter.

Additionally, the labor required for assembly of auxiliary portions and the possibility of manufacturing defects may be reduced.

Effects attainable in the present disclosure are not limited to the above-described effects, and other effects of the present disclosure not yet described will be more clearly understood by those skilled in the art from the following description.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a view showing a connection structure between a busbar assembly and a substrate according to an exemplary embodiment of the present disclosure;

FIG. 2 is a view showing the substrate according to an exemplary embodiment of the present disclosure;

FIG. 3 is a perspective view of a contactor according to an exemplary embodiment of the present disclosure; and

FIG. 4 is a cross-sectional view of the contactor according to the exemplary embodiment of the present disclosure.

### DETAILED DESCRIPTIONS

For embodiments of the present disclosure included herein, specific structural or functional descriptions are exemplary to merely describe the embodiments of the present disclosure, and the embodiments of the present disclosure can be implemented in various forms and should not be interpreted as being limited to the embodiments described in the present specification.

As various modifications can be made and diverse embodiments are applicable to the embodiments according to the concept of the present disclosure, specific embodiments will be illustrated with reference to the accompanying drawings and described in detail herein. However, these specific embodiments should not be construed as limiting the embodiments according to the concept of the present disclosure, but should be construed as extending to all modifications, equivalents, and substitutes included in the concept and technological scope of the disclosure.

Unless defined otherwise, terms used herein including technological or scientific terms have the same meaning as generally understood by those of ordinary skill in the art to which the disclosure pertains. The terms used herein shall be interpreted not only based on the definition of any dictionary but also the meaning that is used in the field to which the disclosure pertains. In addition, unless clearly defined, the terms used herein shall not be interpreted too ideally or formally.

Hereinafter, embodiments of the present disclosure will be described in detail with reference to the accompanying drawings, and the same or similar elements are designated by the same reference numerals regardless of the numerals in the drawings and redundant description thereof will be omitted.

Although “module” or “unit” is suffixed to constituent elements described in the following description, this is intended only for ease of description of the specification. The suffixes themselves have no meaning or function to distinguish the constituent element using the suffix from the constituent element using no suffix.

In the following description of the exemplary embodiments of the present disclosure, a detailed description of known functions and configurations incorporated herein will be omitted when it may obscure the subject matter of the exemplary embodiments of the present disclosure. In addition, the exemplary embodiments of the present disclosure will be more clearly understood from the accompanying drawings and should not be limited by the accompanying drawings, and it is to be appreciated that all changes, equivalents, and substitutes that do not depart from the spirit and technical scope of the present disclosure are encompassed in the present disclosure.

It will be understood that, although the terms “first”, “second”, etc. may be used herein to describe various elements, these elements should not be limited by these terms. These terms are only used to distinguish one element from another.

In the case where an element is "connected" or "linked" to another element, it should be understood that the element may be directly connected or linked to the other element, or another element may be present therebetween. Conversely, in the case where an element is "directly connected" or "directly linked" to another element, it should be understood that no other element is present therebetween.

Unless clearly used otherwise, singular expressions include a plural meaning.

In the present specification, the term "comprising", "including", or the like, is intended to express the existence of the characteristic, the numeral, the step, the operation, the element, the portion, or the combination thereof, and does not exclude another characteristic, numeral, step, operation, element, portion, or any combination thereof, or any addition thereto.

Hereinafter, exemplary embodiments of the present disclosure will be described in detail with reference to the accompanying drawings.

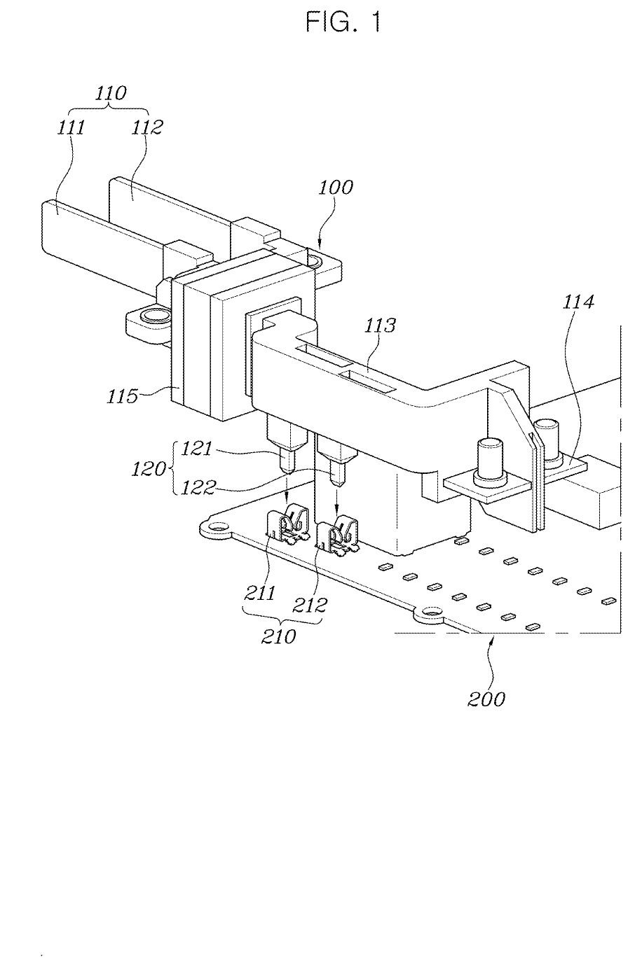

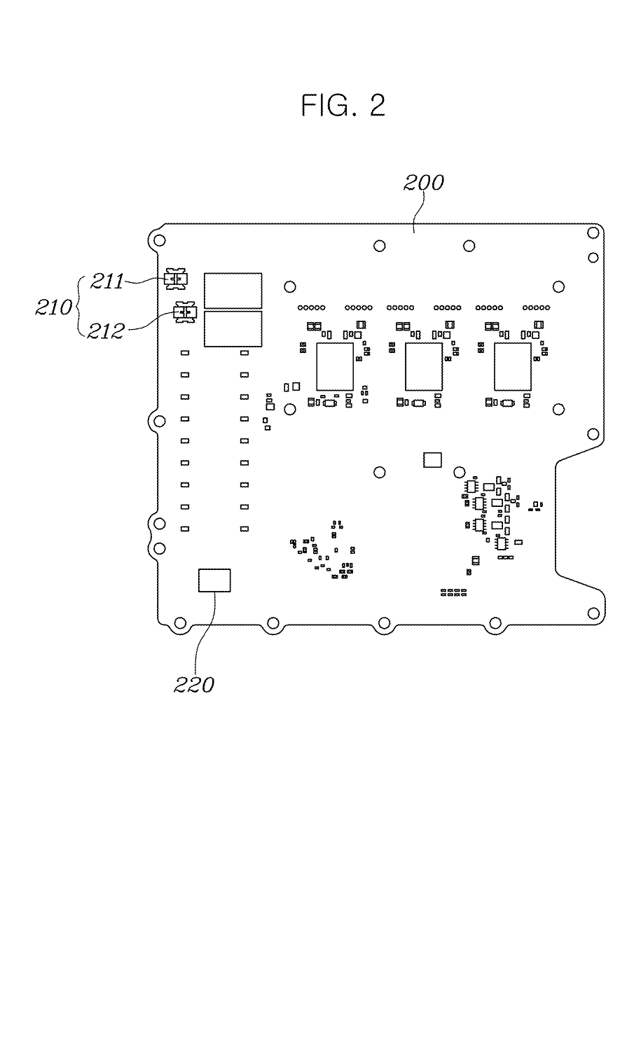

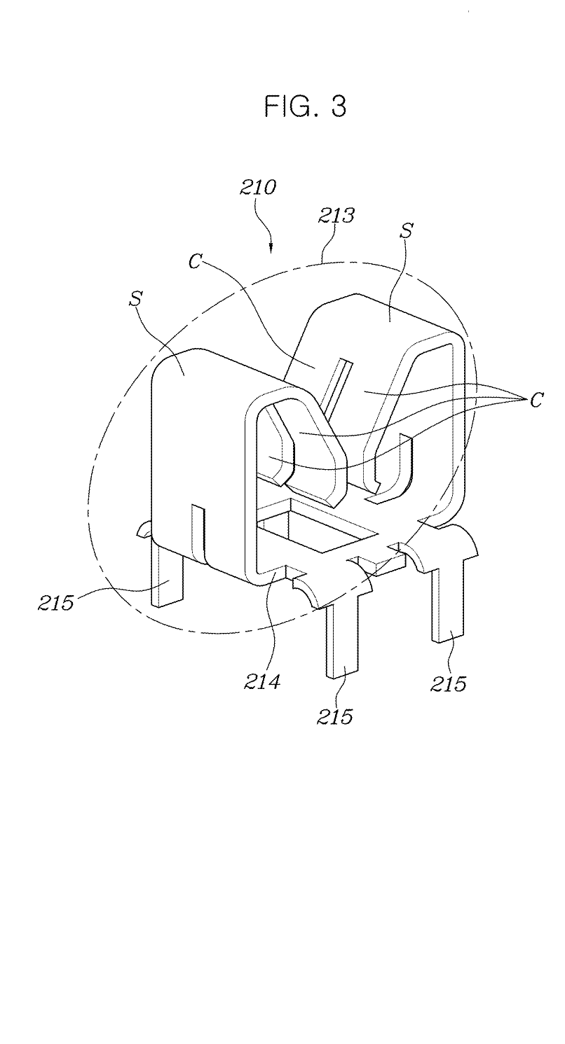

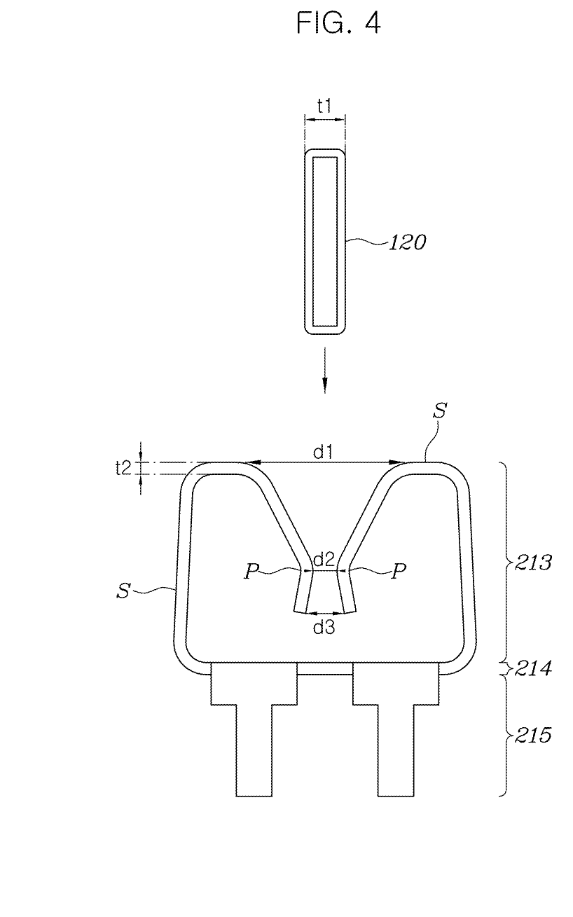

FIG. 1 is a view showing a connection structure between a busbar assembly and a substrate according to an exemplary embodiment of the present disclosure. FIG. 2 is a view showing the substrate according to an exemplary embodiment of the present disclosure. FIG. 3 is a perspective view of a contactor according to an exemplary embodiment of the present disclosure. FIG. 4 is a cross-sectional view of the contactor according to the exemplary embodiment of the present disclosure.

Referring to FIGS. 1, 2,3, and 4, an inverter input voltage sensing apparatus according to an exemplary embodiment of the present disclosure includes a busbar assembly 100 and a substrate 200. The inverter input voltage sensing apparatus according to the exemplary embodiment of the present disclosure may be implemented as a part of the configuration of an inverter within a housing or packaging of the inverter. Alternatively, the inverter input voltage sensing apparatus may also be implemented as a separate configuration connected to the inverter.

The busbar assembly 100 may include a first terminal portion 110 electrically connected to a battery, and a second terminal portion 120 branched from the first terminal portion 110. The substrate 200 may include a contactor 210 into which the second terminal portion 120 is inserted, and a voltage sensor 220 configured to detect a voltage from the battery by receiving the voltage from the busbar assembly 100 through the contactor 210.

The first terminal portion 110 may include a 1-1-th terminal 111 corresponding to a cathode and a 1-2-th terminal 112 corresponding to an anode, and may be connected to a cathode and an anode of the battery through the 1-1-th terminal 111 and the 1-2-th terminal 112, respectively. For example, the second terminal portion 120 may include a 2-1-th terminal 121 branched from the 1-1-th terminal 111 and a 2-2-th terminal 122 branched from the 1-2-th terminal 112, electrically connecting the voltage sensor 220 of the substrate 200 to the cathode of the battery.

In the above-described structure, the busbar assembly 100 and the substrate 200 are directly connected to each other through the second terminal portion 120 and the contactor 210. Accordingly, the connection structure for voltage sensing in the inverter may be simplified.

In accordance with the structure of the exemplary embodiment through the second terminal portion 120 and the contactor 210, the number of components may be reduced, as compared to connection structures that include harnesses with ring terminals, fastening bolts, wires, etc. or connectors for connection thereto. Additionally, such a simplified structure may reduce the installation space. Accordingly, when the voltage sensing apparatus is implemented within the inverter, a free space capable of accommodating other components may be secured within the inverter or the package size of the inverter itself may be reduced. Moreover, as the components and structure are simplified, manufacturing costs may be reduced, and the labor required for assembly of various components and the possibility of manufacturing defects may be reduced.

Additionally, the second terminal portion 120 may be branched toward the contactor 210 in a direction crossing an extension direction of the first terminal portion 110. Accordingly, it may be possible to prevent interference with the first terminal portion 110 during connection between the busbar assembly 100 and the substrate 200.

Meanwhile, the busbar assembly 100 may further include a third terminal portion 114, an insulating portion 113, and a filter portion 115 in addition to the first terminal portion 110 and the second terminal portion 120.

The third terminal portion 114 may be electrically connected to the inverter, and a direct current (DC) voltage from the battery applied to the busbar assembly 100 through the first terminal portion 110 may be supplied to the inverter via the first terminal portion 110 and the third terminal portion 114. To achieve this, the first terminal portion 110 may be connected to an output terminal of the battery, and the third terminal portion 114 may be connected to an input terminal of the inverter.

For example, the second terminal portion 120 may be disposed between the first terminal portion 110 and the third terminal portion 114, and accordingly, may detect an input voltage of the inverter.

The insulating portion 113 may be constituted by an insulator configured to enclose portions of the first terminal portion 110, the second terminal portion 120, and the third terminal portion 114, and accordingly, may ensure insulation from an external environment, except for the battery and the inverter. For example, one end portion of each of the first terminal portion 110, the second terminal portion 120, and the third terminal portion 114 may extend to be exposed to the outside of the insulating portion 113. Accordingly, the first terminal portion 110, the second terminal portion 120, and the third terminal portion 114 may be electrically connected to the battery, the substrate 200, and the inverter through the extended portions thereof.

The filter portion 115 may be disposed on the busbar assembly 100 between the first terminal portion 110 and the second terminal portion 120, and may be implemented using, for example, a ferrite core or the like. The filter portion 115 is configured to suppress electromagnetic interference signals (noise) to stably maintain an input voltage of the inverter.

For example, since the second terminal portion 120 and the third terminal portion 114 are disposed at a downstream end portion of the filter 115 on a current path of the busbar assembly 100, sensing of the input voltage of the inverter through the second terminal portion 120 and supply of the input voltage of the inverter through the third terminal portion 114 may be stably performed.

Meanwhile, the contactor 210 may include a busbar fastener 213 including a plurality of spaced supports S extending from the substrate 200 in a direction toward the second terminal portion 120 under the condition that facing ones of the plurality of supports are bent inwardly toward each other.

The plurality of supports S may be implemented to include a thickness t2 of, for example, 0.3 mm, and an assembly tolerance thereof may be set to 0.4 mm. For example, the plurality of supports S may secure rigidity required for maintenance of contact with the second terminal portion 120, but low stress may be applied to the plurality of supports S, alleviating the risk of destruction or deformation of the plurality of supports S.

For example, the second terminal portion 120 may be inserted between the facing ones of the plurality of supports S spaced apart from each other, and accordingly, may be fastened to the contactor 210. The second terminal portion 120 may be implemented to have a thickness t1 exceeding a minimum distance d2 between the facing ones of the plurality of supports S, pressing the plurality of supports S outwards. Accordingly, contact between the second terminal portion 120 and the contactor 210 may be achieved through reaction force of the plurality of supports S generated due to the pressing. Here, the minimum distance means the distance between the plurality of supports S at a point where the plural supports S are positioned to be nearest to each other.

Additionally, the facing ones of the plurality of supports S may be bent inwardly toward each other so that the distance between the facing supports S gradually decreases (d1 to d2) as the plurality of supports S extends from the side of the second terminal portion 120 toward the side of the substrate 200. In in accordance with the above-described bending structure, reaction force of the plurality of supports S may increase, and accordingly, contact stability between the second terminal portion 120 and the contactor 210 may be enhanced.

Furthermore, the facing ones of the plurality of supports S may be bent inwardly toward each other so that the distance between the facing supports S gradually decreases (d1 to d2) as the plurality of supports S extends from the side of the second terminal portion 120 toward the side of the substrate 200, and may then be bent outwardly away from each other from a point P where inward bending of the facing supports S ends, so that the distance gradually increases (d2 to d3) as the plurality of supports S extends from the point P toward the side of the substrate 200.

In the present structure, the second terminal portion 120 may contact each of the supports S at the point P where inward bending of the plurality of supports S ends. Accordingly, the contact area between the second terminal portion 120 and the contactor 210 may increase.

Meanwhile, each of the supports S may include a plurality of contact portions C formed through branching of an inwardly bent portion thereof. For example, the plurality of contact portions C included in each of the supports S may be branched in directions in which the plurality of supports S faces each other and a direction crossing the direction in which the plurality of supports S extends from the substrate 200. This increases contact points between the second terminal portion 120 and the contactor 210. Accordingly, even if there is shift or deformation in positions or shapes of the contactor 210 and the busbar assembly 100 during assembly or use, contact between the contactor 210 and the busbar assembly 100 may be stably maintained in accordance with the increased contact points.

For example, in a structure disposed with a total of four contact portions C, as shown in FIG. 3, even if twisting occurs at the supports S of the contactor 210 or the second terminal portion 120, causing some contact portions C to be separated from the second terminal portion 120, the remaining contact portions C may be still maintained in a state of contacting with the second terminal portion 120. Accordingly, electrical connection may be maintained, and accordingly, it may be possible to continuously sense the input voltage of the inverter.

To achieve this, the plurality of contact portions C included in facing ones of the plurality of supports S may protrude in directions in which the plurality of supports S faces each other, respectively, to reach the same point. For example, the second terminal portion 120 may contact all of the contact portions C in an initial state.

Meanwhile, the plurality of contact portions C included in facing ones of the plurality of supports S may protrude in a state of being bent inwardly in directions in which the plurality of supports S faces each other, respectively so that the distance between facing ones of the contact portions C gradually decreases (d1 to d2) as the plurality of supports S extends from the side of the second terminal portion 120 toward the side of the substrate 200.

Additionally, the plurality of contact portions C included in facing ones of the plurality of supports S may protrude in a state of being bent inwardly in directions in which the plurality of supports S faces each other, respectively so that the distance between facing ones of the contact portions C gradually decreases (d1 to d2) as the plurality of supports S extends from the side of the second terminal portion 120 toward the side of the substrate 200, and may then protrude in a state of being bent outwardly away from each other from a point P where inward bending of the facing contact portions C ends, so that the distance between the facing contact portions C gradually increases (d2 to d3) as the plurality of supports S extends from the point P toward the side of the substrate 200.

Meanwhile, the contactor 210 may further include a substrate seat 214 and a substrate fastener 215, in addition to the busbar fastener 213. The substrate seat 214 and the substrate fastener 215 may be integrally formed with the busbar fastener 213.

The substrate seat 214 may extend in a plane direction of the substrate 200 and may have, for example, a flat shape or a shape with a through hole centrally formed through a plane of the substrate seat 214. For example, the plurality of supports S may extend from the substrate seat 214 in a direction toward the second terminal portion 120 in a bent state.

The substrate fastener 215 may extend from the substrate seat 214 in a direction toward the substrate 200 in a bent state and may be fastened to the substrate 200 at an extension portion thereof. At least one substrate fastener 215 may be disposed.

Meanwhile, the substrate 200 may be disposed with a first contactor 211 into which the 2-1-th terminal 121 is inserted, and a second contactor 212 into which the 2-2-th terminal 122 is inserted. by the present configuration, a cathode of the second terminal portion 120 may be electrically connected to the substrate 200.

For example, the 2-1-th terminal 121 and the 2-2-th terminal 122 may be branched out from different points on the busbar assembly 100, and accordingly, may be misaligned from each other. The first contactor 211 and the second contactor 212 may be disposed at misaligned positions on the substrate 200, corresponding to positions of the 2-1-th terminal 121 and the 2-2-th terminal 122. Accordingly, it may be possible to prevent interference between poles and to enhance convenience of branching or disposition of the second terminal portion 120 within the busbar assembly 100.

Meanwhile, the substrate 200 may be implemented as, for example, a printed circuit board PCB, and may be connected to the busbar assembly 100 and grounded through the housing of the inverter, etc. Additionally, a plurality of voltage sensors 220 may be disposed at the substrate 200. Each voltage sensor 220 may be implemented using, for example, a resistive element or the like.

In accordance with various embodiments as described above, it may be possible to interconnect the busbar and the voltage sensor through simple components and a connection structure while omitting auxiliary parts such as fastening bolts, wires, connectors, etc.

As the input voltage sensing structure is simplified, it may be possible to reduce manufacturing costs and to reduce the space required for voltage sensing within the inverter.

Additionally, the labor required for assembly of auxiliary parts and the possibility of manufacturing defects may be reduced.

Although the embodiments of the present disclosure have been disclosed for illustrative purposes, those skilled in the art will appreciate that various modifications, additions and substitutions are possible, without departing from the scope and spirit of the present disclosure as disclosed in the accompanying claims.

What is claimed is:

1. An apparatus for sensing an input voltage of an inverter, the apparatus comprising:
a busbar assembly comprising:
a first terminal portion electrically connected to a battery; and
a second terminal portion branched from the first terminal portion; and
a substrate comprising:
a contactor configured to allow the second terminal portion to be inserted into the contactor; and
a voltage sensor configured to detect the voltage of the battery by receiving the voltage of the battery from the busbar assembly through the contactor.

2. The apparatus of claim 1, wherein the contactor comprises a busbar fastener including a plurality of spaced supports extended from the substrate in a direction toward the second terminal portion and bent inwardly, facing each other.

3. The apparatus of claim 2, wherein the second terminal portion is inserted between the plurality of spaced supports.

4. The apparatus of claim 3, wherein the second terminal portion has a thickness exceeding a minimum distance between the plurality of spaced supports.

5. The apparatus of claim 2, wherein the plurality of supports are bent inwardly toward each other so that a distance between the plurality of supports decreases as the plurality of supports extend from a side of the second terminal portion toward a side of the substrate.

6. The apparatus of claim 2, wherein the plurality of supports are bent inwardly toward each other so that a distance between the plurality of supports decreases as the plurality of supports extends from a side of the second terminal portion toward a side of the substrate, and are then bent outwardly away from each other from a point where inward bending of the plurality of supports ends, so that the distance increases as the plurality of supports extends from the point toward the side of the substrate.

7. The apparatus of claim 6, wherein the second terminal portion contacts each of the plurality of supports at the point where the inward bending of the plurality of supports ends.

8. The apparatus of claim 2, wherein each of the plurality of supports comprises a plurality of contact portions formed by branching of an inwardly bent portion thereof.

9. The apparatus of claim 8, wherein the plurality of contact portions comprised in each of the plurality of supports is branched in directions crossing a direction in which the plurality of supports faces each other and a direction in which the plurality of supports extends from the substrate.

10. The apparatus of claim 8, wherein the plurality of contact portions comprised in the plurality of supports protrudes in directions in which the plurality of supports faces each other, respectively, to reach a same point.

11. The apparatus of claim 10, wherein the plurality of contact portions comprised in the plurality of supports protrudes in a state of being bent inwardly in directions in which the plurality of supports faces each other, respectively so that a distance between the plurality of contact portions decreases as the plurality of supports extends from a side of the second terminal portion toward a side of the substrate.

12. The apparatus of claim 10, wherein the plurality of contact portions comprised in the plurality of supports protrudes in a state of being bent inwardly in directions in which the plurality of supports faces each other, respectively so that a distance between the plurality of contact portions decreases as the plurality of supports extends from a side of the second terminal portion toward a side of the substrate, and then protrude in a state of being bent outwardly away from each other from a point where inward bending of the plurality of contact portions ends, so that the distance between the facing contact portions increases as the plurality of supports extends from the point toward the side of the substrate.

13. The apparatus of claim 8, wherein the second terminal portion contacts all of the plurality of contact portions.

14. The apparatus of claim 2,
wherein the contactor further comprises a substrate seat extending in a plane direction of the substrate, and
wherein the plurality of supports extends from the substrate seat in a direction toward the second terminal portion in a bent state.

15. The apparatus of claim 14, wherein the contactor further comprises a substrate fastener extending from the substrate seat in a direction toward the substrate in the bent state and fastened to the substrate at an extension portion thereof.

16. The apparatus of claim 1, wherein the second terminal portion is branched toward the contactor in a direction crossing an extension direction of the first terminal portion.

17. The apparatus of claim 1,
wherein the busbar assembly further comprises a third terminal portion electrically connected to the inverter, and
wherein the second terminal portion is disposed between the third terminal portion and the first terminal portion and the third terminal portion is formed at a side opposite to the first terminal portion.

18. The apparatus of claim 1,
wherein the first terminal portion comprises:
a first terminal corresponding to a cathode; and
a second terminal corresponding to an anode, and
wherein the second terminal portion comprises:
a first terminal branched from the first terminal of the first terminal portion; and
a second terminal branched from the second terminal of the first terminal portion.

19. The apparatus of claim 18,
wherein the contactor includes a first contactor and a second contactor, and
wherein the substrate is disposed with the first contactor configured to allow the first terminal of the second terminal portion to be inserted into the first contactor, and the second contactor configured to allow the second terminal of the second terminal portion to be inserted into the second contactor.

20. The apparatus of claim 19,
wherein the first terminal and the second terminal of the second terminal portion are branched out from different points on the busbar assembly, and
wherein the first contactor and the second contactor are disposed at misaligned positions on the substrate, corresponding to positions of the first terminal and the second terminal of the second terminal portion.
